(19) United States
(12) Patent Application Publication
(10) Pub. No.: US 2014/0132327 A1
(43) Pub. Date: May 15, 2014

(54) CHARGE PUMP MODULE AND VOLTAGE GENERATION METHOD THEREOF

(71) Applicant: NOVATEK MICROELECTRONICS CORP., Hsinchu (TW)

(72) Inventor: Jen-Hao Liao, Hsinchu County (TW)

(73) Assignee: NOVATEK MICROELECTRONICS CORP., Hsinchu (TW)

(21) Appl. No.: 13/831,746

(22) Filed: Mar. 15, 2013

(30) Foreign Application Priority Data
Nov. 12, 2012 (TW) 101142075

(51) Int. Cl. H03K 5/08

(52) U.S. Cl. CPC H03K 5/088
USPC 327/316

(57) ABSTRACT

A charge pump module including a ratio control circuit and a charge pump circuit is provided. The ratio control circuit provides a boost ratio based on a control signal. The ratio control circuit includes at least two ratio generation circuits having different boost ratios. The ratio control circuit dynamically switches between the ratio generation circuits to adjust the provided boost ratio based on the control signal. The charge pump circuit is coupled to the ratio control circuit. The charge pump circuit receives an input voltage and converts the input voltage into an output voltage based on the boost ratio provided by the ratio control circuit. Furthermore, a voltage generation method of a charge pump module is also provided.

### CROSS-REFERENCE TO RELATED APPLICATION

This application claims the priority benefit of Taiwan application serial no. 101142075, filed on Nov. 12, 2012. The entirety of the above-mentioned patent application is hereby incorporated by reference herein and made a part of this specification.

### BACKGROUND OF THE DISCLOSURE

1. Field of the Invention

The invention generally relates to a voltage generation module and a voltage generation method thereof, and more particularly, to a charge pump module and a voltage generation method thereof.

2. Description of Related Art

An electronic circuit often needs various power supply voltages having different voltage levels, and thus a charge pump circuit is usually configured to use the existing power supply voltage to generate various power supply voltages of different voltage levels. The charge pump circuit generates the voltages of different levels by boosting (or bucking) the input voltage with a predetermined multiple. Therefore, the levels of the output voltage of the charge pump circuit are related to the input voltage.

However, in order to extend the applications of the charge pump circuit in various environments (i.e., the input voltage is uncertain when the charge pump circuit is designed) to generate the expected output voltages, the received input voltage is usually first detected by utilizing a voltage detection circuit, and a predetermined boost ratio is determined accordingly, such that the level of output voltage is adjusted to a rated voltage, and then a rated output voltage is generated by the charge pump. The boost ratio determined by such method may only be selected from many predetermined ratios, and unable to adjust the boost ratio according to the practical design requirement. Therefore, the rated output voltage may be higher than a voltage that is required for the circuit of the next stage, and thus it may waste on more power.

### SUMMARY OF THE DISCLOSURE

Accordingly, the disclosure is directed to a charge pump module that can adaptively adjust its boost ratio to reduce power consumption.

The disclosure is directed to a voltage generation method of a charge pump module that can adaptively adjust a boost ratio of the charge pump module to reduce power consumption.

The disclosure provides a charge pump module including a ratio control circuit and a charge pump circuit. The ratio control circuit is configured to provide a boost ratio according to a control signal. The ratio control circuit includes at least two ratio generation circuits having different boost ratios. In addition, the ratio control circuit dynamically switches between the ratio generation circuits to adjust the boost ratio provided by the ratio control circuit. The charge pump circuit is coupled to the ratio control circuit. The charge pump circuit is configured to receive an input voltage and convert the input voltage into an output voltage according to the boost ratio provided by the ratio control circuit.

According to an embodiment of the disclosure, the control signal includes a first period and a second period. During the first period, the ratio control circuit switches to one of the ratio generation circuits. During the second period, the ratio control circuit switches to another one of the ratio generation circuits.

According to an embodiment of the disclosure, the charge pump module further comprises a voltage detection circuit. The voltage detection circuit is coupled to the charge pump circuit and the ratio control circuit. The voltage detection circuit detects the output voltage, and accordingly provides the control signal to the ratio control circuit.

According to an embodiment of the disclosure, the control signal includes a first period and a second period. The voltage detection circuit compares the output voltage with a first threshold value and a second threshold value to determine a duty cycle of the first period and the second period of the control signal.

According an embodiment of the disclosure, the first threshold value is greater than the second threshold value. According to a detection result of the voltage detection circuit, if the output voltage is less than the second threshold, the ratio control circuit switches to one of the ratio generation circuits having a higher boost ratio according to the control signal. If the output voltage is greater than the first threshold value, the ratio control circuit switches to one of the ratio generation circuits having a lower boost ratio according to the control signal.

According to an embodiment of the disclosure, the first threshold value and the second threshold value is determined according to a predetermined target value of the output voltage.

According to an embodiment of the disclosure, the ratio control circuit further includes a ratio selection circuit. The ratio selection circuit is coupled to the ratio generation circuits. The ratio selection circuit is configured to dynamically switch to one of the ratio generation circuits.

According to an embodiment of the disclosure, the boost ratio of the ratio generation circuits is negative. In addition, the charge pump circuit provides the negative output voltage according to the negative boost ratio provided by the ratio control circuit.

According to an embodiment of the disclosure, the boost ratio of the ratio generation circuits is positive. In addition, the charge pump circuit provides the positive output voltage according to the positive boost ratio provided by the ratio control circuit.

According to an embodiment of the disclosure, the boost ratio provided by the ratio control circuit is between the maximum boost ratio and the minimum boost ratio of the switched generation circuits.

Accordingly, the disclosure is directed to a voltage generation method of a charge pump module. The charge pump module includes a ratio control circuit and a charge pump circuit. The ratio control circuit includes at least two ratio generation circuits having different boost ratios. The voltage generation method includes the following steps. According to a control signal, a boost ratio outputted to the charge pump circuit is adjusted by dynamically switching between the ratio generation circuits. According the boost ratio outputted to the charge pump circuit, an input voltage is converted into an output voltage.

According to an embodiment of the disclosure, the control signal includes a first period and a second period, and the step of dynamically switching between the ratio generation circuits includes the following steps. During the first period, one of the ratio generation circuits is switched according to the control signal. During the second period, another one of the ratio generation circuit is switched to according to the control signal.

According to an embodiment of the disclosure, the voltage generation method further includes a step of detecting the output voltage and accordingly providing the control signal.

According to an embodiment of the disclosure, the control signal includes a first period and a second period. The step of detecting the output voltage and accordingly providing the control signal includes a step of comparing the output voltage with a first threshold value and a second threshold value to determine a duty cycle of the first period and the second period of the control signal.

According to an embodiment of the disclosure, the first threshold value is greater than the second threshold value. The step of comparing the output voltage with the first threshold value and the second threshold value includes the following steps. If the output voltage is less than the second threshold value, one of the ratio generation circuits having a higher boost ratio is switched according to the control signal. If the output voltage is greater than the first threshold value, one of the ratio generation circuits having a lower boost ratio is switched according to the control signal.

According to an embodiment of the disclosure, the first threshold value and the second threshold value are determined according to a predetermined target value of the output voltage.

According to an embodiment of the disclosure, the boost ratio of the ratio generation circuits is negative value, and in the step of converting the input voltage into the output voltage, the negative output voltage is provided according to the negative boost ratio outputted to the charge pump circuit.

According to an embodiment of the disclosure, the boost ratio of the ratio generation circuits is positive value, and in the step of converting the input voltage into the output voltage, the positive output voltage is provided according to the positive boost ratio outputted to the charge pump circuit.

According to an embodiment of the disclosure, the boost ratio outputting to the charge pump circuit is between the maximum boost ratio and the minimum boost ratio of the switched ratio generation circuits.

In the view of above, in the exemplary embodiments of the disclosure, the charge pump module dynamically switches between various boost ratios, so as to adaptively adjust an equivalent ratio value that is between the switched ratios.

In order to make the aforementioned and other features and advantages of the invention comprehensible, several exemplary implementations accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a diagram illustrating a charge pump module of relative technique according to the embodiment of the disclosure.

FIG. 2 is a diagram illustrating a charge pump module according to an embodiment of the disclosure.

FIG. 3 is a waveform diagram illustrating a control signal and an output voltage according to an embodiment of the disclosure.

FIG. 4 is a diagram illustrating a charge pump module according to yet another embodiment of the disclosure.

FIG. 5 is a waveform diagram illustrating a control signal and an output voltage according to yet another embodiment of the disclosure.

FIG. 6 is a flow chart illustrating a voltage generation method of the charge pump module according to an embodiment of the disclosure.

FIG. 7 is a diagram illustrating a charge pump module according to yet another embodiment of the disclosure.

FIG. 8 is a waveform diagram illustrating a control signal and an output voltage according to yet another embodiment of the disclosure.

FIG. 9 is a circuit diagram illustrating a voltage detection circuit according to an embodiment of the disclosure.

FIG. 10 is a diagram illustrating a charge pump module according to yet another embodiment of the disclosure.

FIG. 11 is a waveform diagram illustrating a control signal and an output voltage according to yet another embodiment of the disclosure.

FIG. 12 is a flow chart illustrating a voltage generation method of a charge pump module according to yet another embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

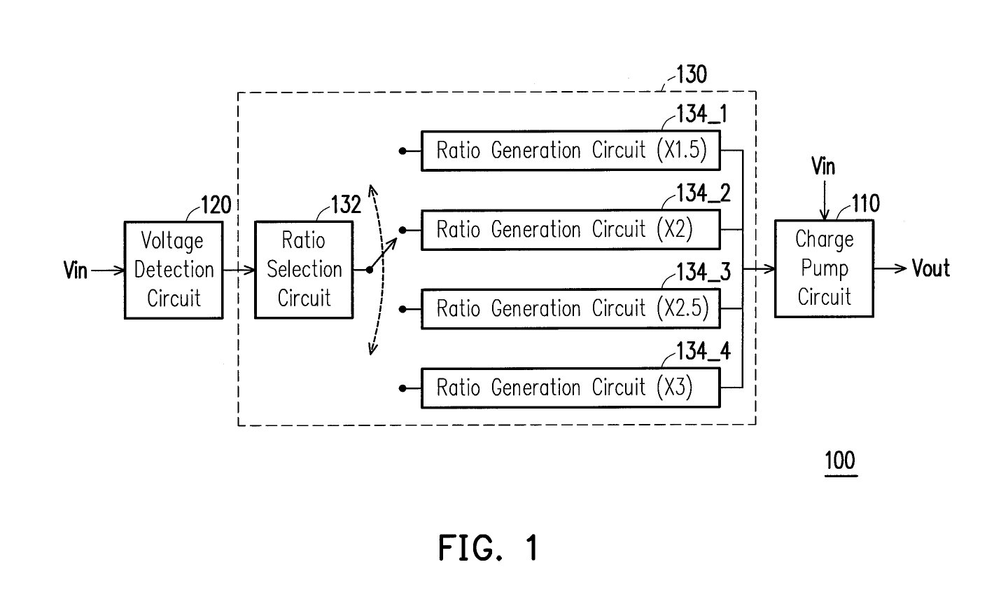

FIG. 1 is a diagram illustrating a charge pump module of relative technique according to the embodiment of the disclosure. With reference to FIG. 1, in the present embodiment, the main design requirement of a charge pump module 100 is to ensure that an output voltage Vout outputted by a charge pump circuit 110 is not lower than the application requirements. For example, under the condition that at least an input voltage Vin between 2.3 volt and 4.8 volt is needed to satisfy the application requirement, the charge pump circuit 110 is required to have capability of providing the output voltage Vout greater than 5 volt. At the same time, the load current is between 0 milliamp (mA) to 10 mA.

In the example, a voltage detection circuit 120 detects the amount of the input voltage Vin as a basis for the switching ratio of a ratio selection module 130. Under the operation of the input voltage Vin having higher voltage, the ratio selection module 130 switches to a ratio generation circuit having a lower ratio, which satisfies the requirement of the output voltage Vout as well as conserves power. On the contrary, under the operation of the input voltage Vin having a lower voltage, the ratio selection module 130 switches to a ratio generation circuit having a higher ratio in order to satisfy the voltage requirement of the output voltage Vout. For example, when the output voltage Vout is within a range of 3.7 volt to 4.5 volt, the ratio selection module 130 is switched to a ratio generation circuit 134_1. When the output voltage is within a range of 3 volt to 3.7 volt, the ratio selection module 130 switches to a ratio generation circuit 134_2. When the output voltage is within a range of 2.5 volt to 3 volt, the ratio selection module 130 switches to a ratio generation circuit 134_4. When the output voltage is 2.5 volt or below, the ratio selection module 130 switches to a ratio generation circuit 134_4.

Therefore, in order to satisfy the requirements described above, the ratio selection module 130 may includes four ratio generation circuits having different ratios 134_1 thru 134_4, that is, X1.5, X2, X2.5, and X3, so as to provide various selections of different ratios. According to the maximum load current required by the output terminal, a ratio selection circuit 132 of the ratio selection module 130 determines which one of the ratios is to select with respect to the amount of the input voltage Vin, so as to attain the required output voltage Vout, and the selected ratio determines the current consumption. However, this type of design is unable to switch the ratio in accordance with different load current variations, in order to satisfy the requirement of power conservation. That is, the charge pump module 100 selects a ratio out of some fixed ratios, and unable to adjust the required boost ratio according to the amount of input voltage and the amount of the load current, which creates an input current that is equal to the load current multiply by the boost ratio, and generating excessive current consumption. Furthermore, while designing a different ratio generation circuit, it requires different circuit configurations so as to obtain the desired boost ratios. Therefore, more ratio selection increases the design complexity of the charge pump circuit, the layout area occupied by the circuit, and reduces the driving ability of the charge pump.

In the exemplary embodiments of the disclosure, the charge pump module dynamically switches between various boost ratios according to the control signal, so as to generate a ratio value equivalent to a ratio between the switched boost ratios. In an embodiment, the charge pump can auto adjust the ratio by detecting the voltage level of output voltage, so as to conserve power. In order to make the embodiments of the disclosure comprehensible, at least one embodiment accompanying with figures is described in detail below.

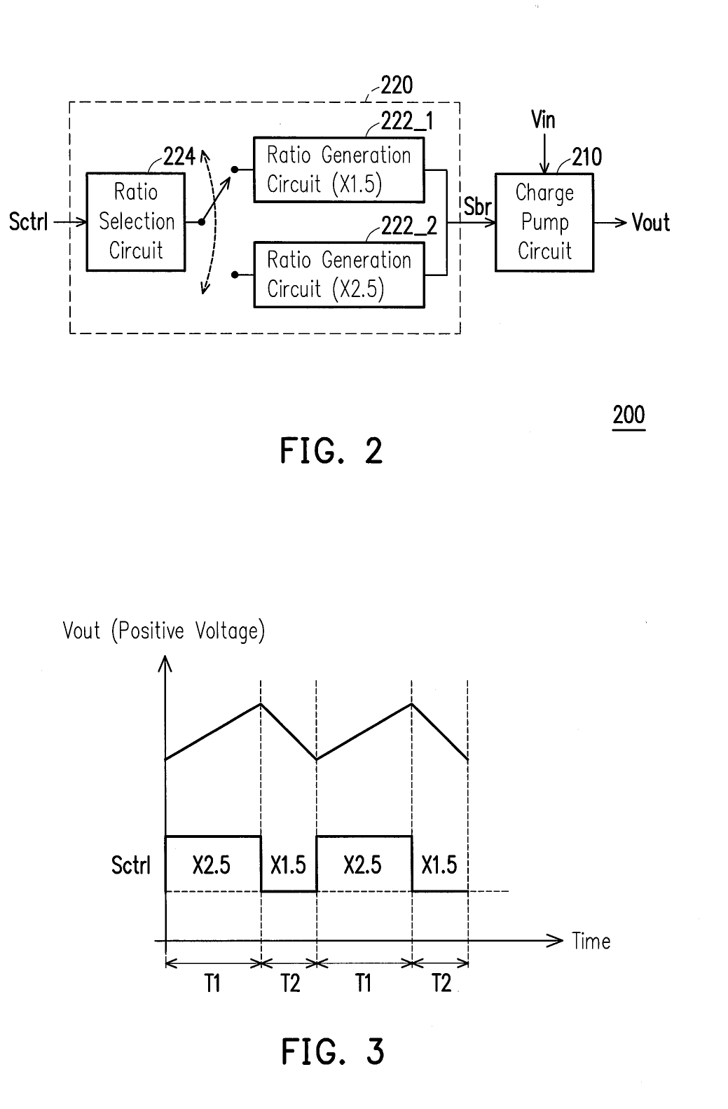

FIG. 2 is a diagram illustrating a charge pump module according to an embodiment of the disclosure. With reference to FIG. 2, a charge pump module 200 of the present embodiment includes a charge pump circuit 210 and a ratio control circuit 220. The ratio control circuit 220 provides a boost ratio Sbr according to a control signal Sctrl, where the boost ratio can be adjusted according to the requirements of the practical design, and it is not limited to a selection of some fixed ratios. Therefore, the ratio control circuit 220 of the embodiment includes a ratio selection circuit 224 and at least two ratio generation circuits having different boost ratios 222_1 and 222_2, which includes X1.5 and X2.5, these ratios are utilized for illustrations, and the disclosure is not limited thereto. The ratio selection circuit 224 is coupled to the ratio generation circuits 222_1 and 222_2, and configured to dynamically switch between the ratio generation circuits 222_1 and 222_2 according to the control signal Sctrl, so as to adjust the boost ratio Sbr. The charge pump circuit 210 is coupled to the ratio control circuit 210, which is configured to receive an input voltage Vin, and converts the input voltage Vin into an output voltage Vout according to the boost ratio Sbr provided by the ratio control circuit 220, and then the output voltage Vout is outputted to the next load circuit (not shown).

In the present embodiment, the adjustment of the boost ratio is to switch between the ratio generation circuits 222_1 and 222_2 through a time-sharing setting, so as to attain the driving capability and the power consumption equivalent to a boost ratio between the boost ratios of the ratio generation circuits 222_1 and 222_2. FIG. 3 is a waveform diagram illustrating the control signal and the output voltage according to an embodiment of the disclosure. With reference to FIGS. 2 and 3, the control signal Sctrl described in the present embodiment includes a first period T1 and a second period T2. During a first period T1, the control signal Sctrl is configured in high level, and accordingly, the ratio selection circuit 224 switches to the ratio generation circuit 222_2 having a ratio of X2.5. During a second period T2, the control signal Sctrl is configured in low level, and accordingly, the ratio selection circuit 224 switches to the ratio generation circuit 222_1 having a ratio of X1.5. Taking the charge pump circuit 210 providing a positive voltage as an example, during the first period T1, the ratio selection circuit 224 is switched to the ratio generation circuit 222_2 having the ratio of X2.5, therefore, the output voltage Vout having positive voltage outputted by the charge pump circuit 210 increases along with time. Next, when the cycle of the control signal Sctrl switches to the second period T2, the ratio selection circuit 224 switches to the ratio generation circuit 222_1 having a ratio of X1.5, so the output voltage Vout having positive voltage outputted by the charge pump circuit 210 decreases along with time. Therefore, through adjusting the ratio of the first period T1 and the second period T2, the ratio adjustment method illustrated in the present embodiment satisfies the requirement of the circuit application as well as reducing the power consumption by utilizing the control signal Sctrl in response to different output voltages Vout and current loads. The result of ratio adjustment described in the embodiment is, for example, a boost ratio Sbr between the ratio of X1.5 and X2.5, the ratio control circuit 220 is not limited to a selection of the higher ratio out of the ratios of X1.5 and X2.5 for satisfying the voltage requirement of the application, which results in more power consumption.

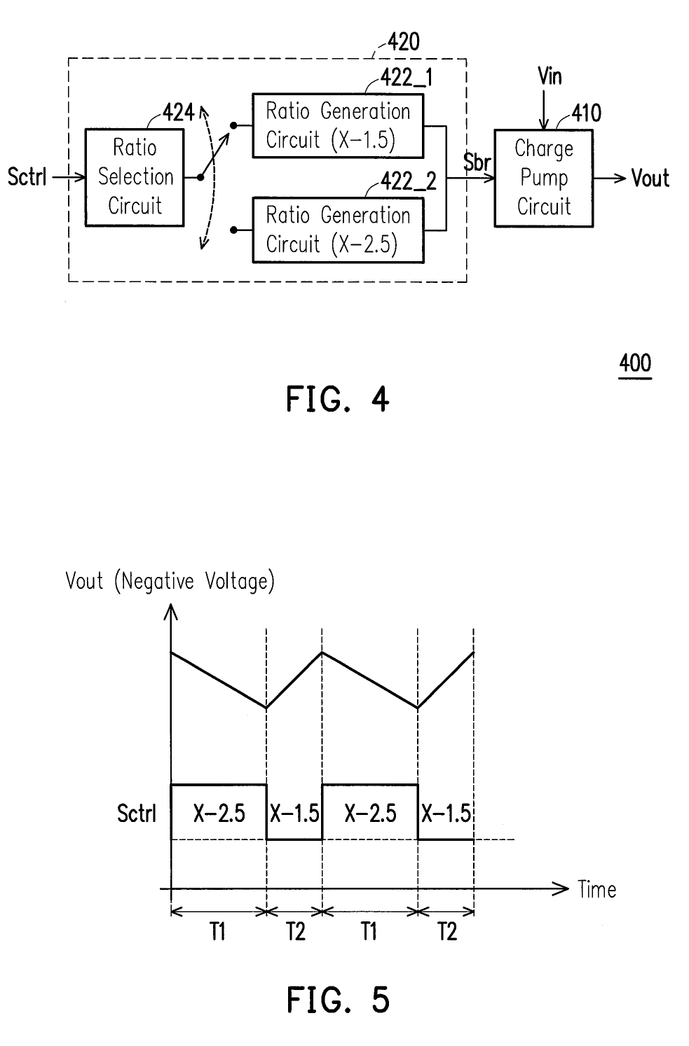

In the above embodiment, the boost ratios X1.5 and X2.5 of the ratio generation circuits 222_2 and 222_2 are positive values. The charge pump circuit 210 provides the positive output voltage Vout according the positive boost ratio Sbr provided by the ratio control circuit 220, however, the concept of the ratio adjustment described in the disclosure is not limited to the charge pump circuit 210 that provides a positive voltage. The disclosure may also be applied to a charge pump circuit that provides a negative voltage. FIG. 4 is a diagram illustrating a charge pump module according to yet another embodiment of the disclosure. FIG. 5 is a waveform diagram illustrating the control signal and the output voltage according to yet another embodiment of the disclosure. With reference to FIGS. 4 and 5, a charge pump module 400 of the present embodiment is similar to the charge pump module 200 illustrated in FIG. 2. The main difference between the embodiments illustrated in FIGS. 2 and 4 is that the boost ratios of two ratio generation circuits 422_1 and 422_2 in a ratio control circuit 420 are respectively X-1.5 and X-2.5, for example. However, these ratios are used for illustration, and the disclosure is not limited thereto. In the application of the charge pump circuit 410 providing negative voltage, during the first period T1, since the ratio selection circuit 424 is switched to the ratio generation circuit 422_2 having the ratio of X-2.5, the negative output voltage Vout outputted by the charge pump circuit 410 decreases along with time. Next, when the timing of the control signal Sctrl switches to the second period T2, the ratio selection circuit 424 switches to the ratio generation circuit 422_1 having the ratio of X-1.5, so that the negative output voltage Vout outputted by the charge pump circuit 410 increases along with time. Therefore, the ratio adjustment result of the embodiment is, for example, the boost ratio Sbr that is between the ratios of X-1.5 and X-2.5. Therefore, in the present embodiment the boost ratio of the ratio generation circuits 422_1 and 422_2 is negative value. In addition, the charge pump circuit 410 provides the negative output voltage Vout according to the negative boost ratio Sbr provided by the ratio control circuit 420.

It should be noted that, in the embodiments illustrated in FIGS. 2 and 4, the ratio control circuit including at least two ratio generation circuits is used for illustration. However, the ratio control circuit of the disclosure may also include a plurality of ratio generation circuits, for example, four ratio generation circuits having different ratios. In such embodiment, according to the configured control signal Sctrl, the ratio selection circuit may switch between the ratio generation circuits, where the boost ratio Sbr outputted by the ratio control circuit is between a maximum boost ratio and a minimum boost ratio of the ratio generation circuits being switched. For example, the ratio selection circuit includes four ratio generation circuits having four different ratios of X1.5, X2, X2.5, and X3. The ratio selection circuit adjusts the operation time of the ratio generation circuits having the ratios of X2 and X3 according to the configured control signal Sctrl, and constantly switches between these two ratio generation circuits, so as to attain a boost ratio equivalent to the ratio of X2.5. Therefore, in the example, the ratio control circuit can be selectively configured without the ratio generation circuit having the ratio of X2.5, so as to reduce the circuit design complexity and layout area of the charge pump module.

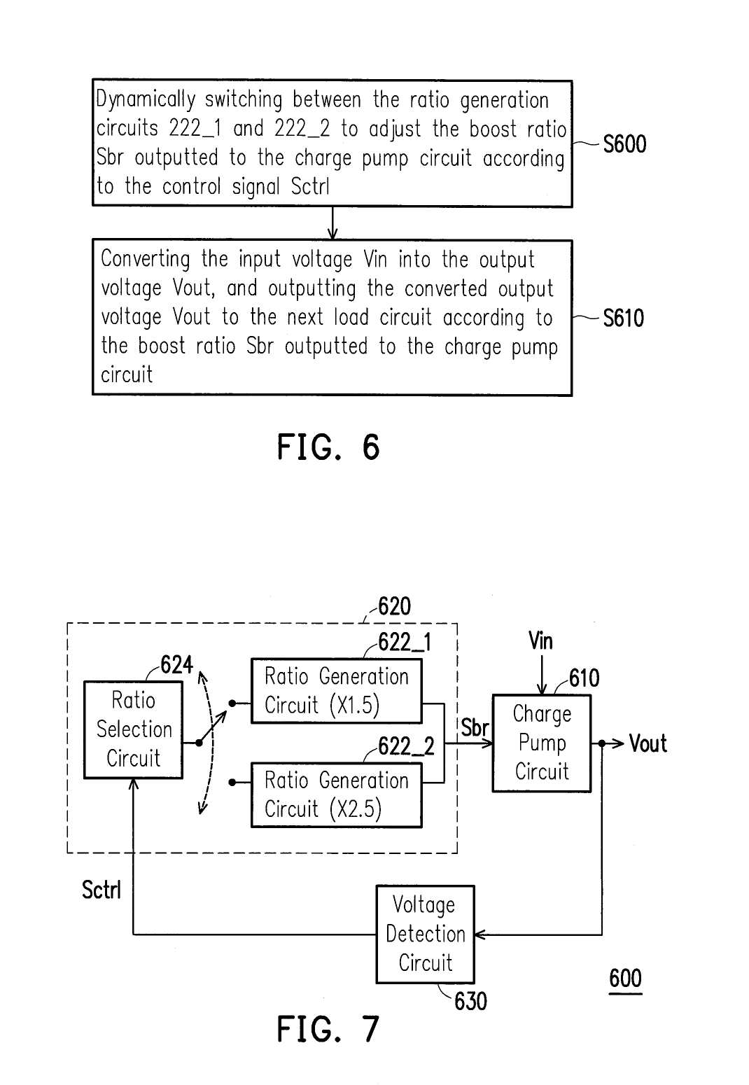

FIG. 6 is a flow chart illustrating a voltage generation method of a charge pump module according to an embodiment of the disclosure. With reference to FIGS. 2 and 6, the voltage generation method of the present embodiment is adapted to, for example, the charge pump module 200 illustrated in FIG. 2, which includes the following steps. First of all, in step S600, according to control signal Sctrl, the boost ratio Sbr outputted to the charge pump circuit is adjusted by dynamically switching between the ratio generation circuits 222_1 and 222_2. Afterward, in step S610, according to the boost ratio Sbr outputted to the charge pump circuit, the input voltage Vin is converted into the output voltage Vout, and then outputted to the next load circuit (not shown).

Furthermore, the voltage generation method of the embodiment of the disclosure is sufficiently taught, suggested, and embodied in the embodiments illustrated in FIG. 2 thru FIG. 5, and therefore no further description is provided here.

In the disclosure, there are various methods for the charge pump module to configure and adjust the timing of the control signal Sctrl, where one of the embodiments may be implemented by detecting the output voltage Vout. FIG. 7 is a diagram illustrating a charge pump module according to yet another embodiment of the disclosure. With reference to FIG. 7, a charge pump module 600 of the present embodiment is similar to the charge pump module 200 illustrated in FIG. 2, and main difference between two is that the charge pump module 600 further includes a voltage detection circuit 630. The voltage detection circuit 630 is coupled to the charge pump circuit 610 and the ratio control circuit 620, and is configured to detect the output voltage Vout so as to provide control signal Sctrl to the ratio control circuit 620 accordingly.

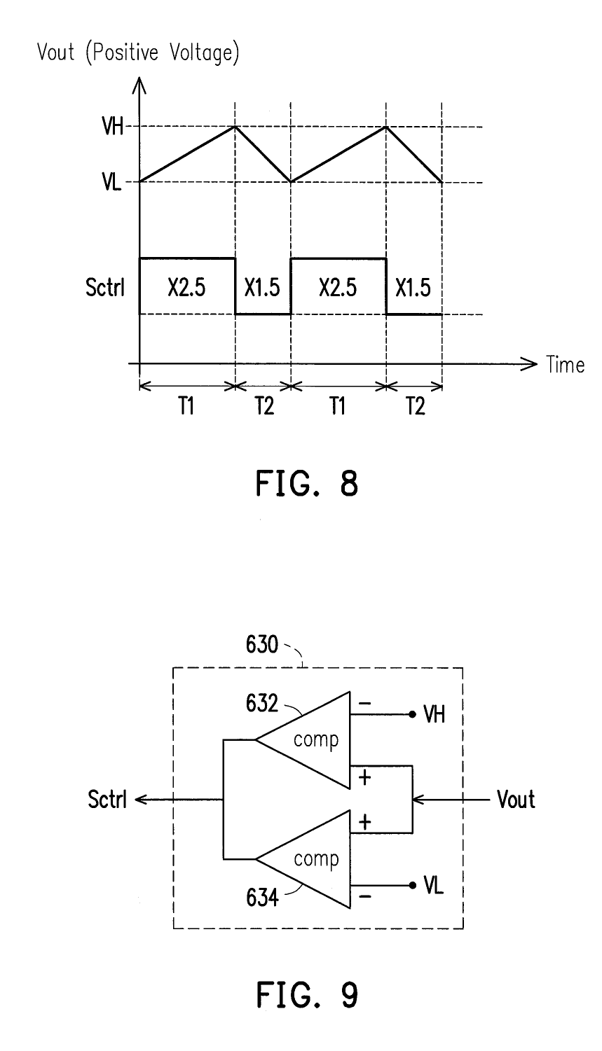

FIG. 8 is a waveform diagram illustrating the control signal and the output voltage according to yet another embodiment of the disclosure. FIG. 9 is a circuit diagram illustrating a voltage detection circuit according to an embodiment of the disclosure. With reference to FIG. 7 thru FIG. 9, in the embodiment, the voltage detection circuit 630 compares the output voltage Vout with a first threshold value VH and a second threshold value VL, so as to determine a duty cycle of the first period T1 and the second period T2 of the control signal Sctrl. The voltage detection circuit 630 illustrated in the embodiment includes two comparators 632 and 634, the non-inverting terminals of the comparators are configured to receive the output voltage Vout, the inverting terminals of the comparators are configured to receive the first threshold value VH and the second threshold value VL, respectively, such as the illustration shown in FIG. 9. In the application of the output voltage Vout, the first threshold value VH and the second threshold value VL are positive, and the first threshold value VH is greater than the second threshold value VL.

In the present embodiment, according to a detection result of the voltage detection circuit 630, if the output voltage Vout is less than the second threshold value VL, the ratio control circuit 620 switches to the ratio generation circuit having a higher boost ratio according to the control signal Sctrl, such as switching to the ratio generation circuit 622_2 having the ratio of X2.5. On the contrary, if the output voltage Vout is greater than the first threshold VH, the control circuit 620 switches to the ratio generation circuit having a lower boost ratio according to the control signal Sctrl, such as switching to the ratio generation circuit 622_1 having the ratio of X1.5. According to a simulation result, under the operation of such circuit configuration having a current load of 14 mA, the proportion of time (i.e., duty cycle) occupied by the second period T2, i.e., switched to the ratio of X1.5, is greater than the first period T1, i.e., switched to the ratio of X2.5. Under the operation while the current load is 26 mA, the proportion of time (i.e., duty cycle) occupied by the first period T1, i.e., switched to the ratio of X2.5, is greater than the second period T2, i.e., switched to the ratio of X1.5. Furthermore, in the exemplary embodiment of the disclosure, the first threshold value VH and the second threshold value VL are determined according to a predetermined target value of the output voltage Vout. In the example, the first threshold value VH is configured to 5.5 volt, and the second threshold value VL is configured to 5 volt, however, the disclosure is not limited thereto.

The voltage detection circuit 630 of the embodiment detects the output voltage Vout, and the charge pump circuit 610 configures the first threshold value VH as the maximum voltage of the output voltage Vout and the second threshold VL as the minimum voltage of the output voltage Vout, where the second threshold value VL can be configured as the minimum voltage of the application requirement. When the output voltage Vout is lower than the second threshold value VL, which representing the voltage multiplying capability of the ratio at that moment is unable to satisfy the application requirement, the ratio control circuit 620 switches to a higher boost ratio at the next timing cycle. On the contrary, when the output voltage Vout is higher than a predetermined value of the first threshold value VH, the ratio control circuit 620 switches to a lower boost ratio at the next timing cycle, so as to reduce power consumption.

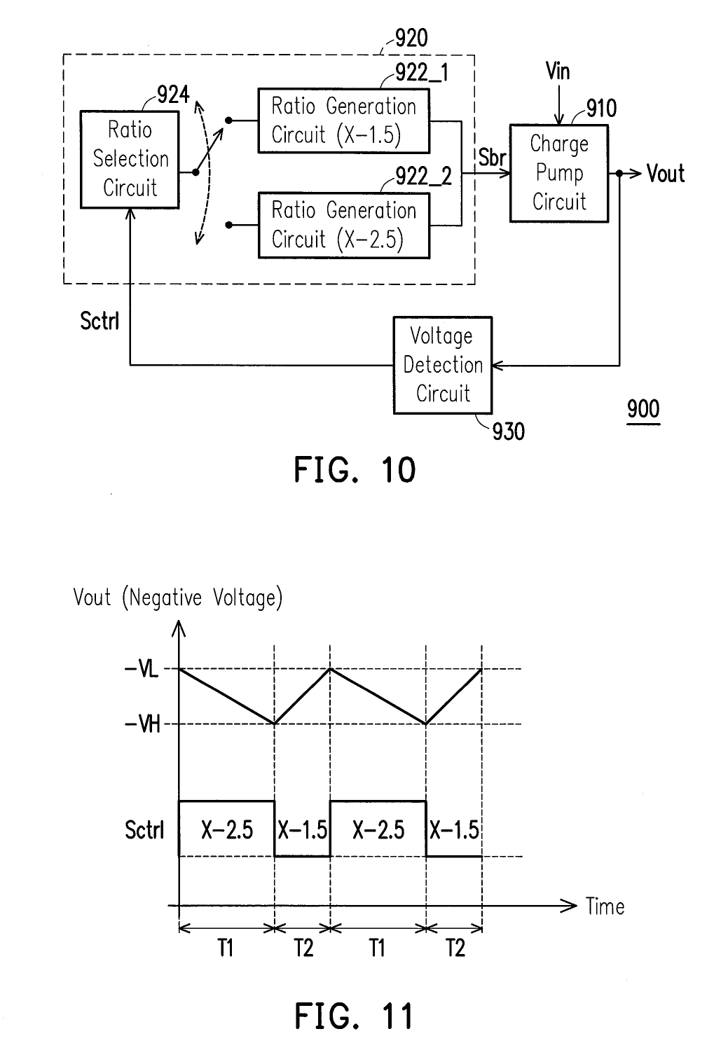

Such concept of configuring the control signal Sctrl by detecting the output voltage is not limited to the charge pump circuit 610 providing the positive voltage. It may be applied to a charge pump circuit providing a negative voltage as well. FIG. 10 is a diagram illustrating a charge pump module according to yet another embodiment of the disclosure. FIG. 11 is a waveform diagram illustrating the control signal and the output voltage according to yet another embodiment of the disclosure. With reference to FIGS. 10 and 11, a charge pump module 900 illustrated in the present embodiment is similar to the charge pump module 600 illustrated in FIG. 7. The main difference between these two charge pump modules is that the ratio control circuit 920 switches between the boot ratio of X-1.5 and X-2.5, for example. The ratios mentioned above are used for illustration, and it is not intended to limit the disclosure. In addition, values of the first threshold value VH and the second threshold value VL are adjusted dynamically. In the example, the first threshold value −VL is configured to, for example, −5 volt and the second threshold value −VH to, for example, −5.5 volt, however the disclosure is not limited thereto. Therefore, in the application of the charge pump circuit 910 providing the negative voltage, according to a detection result of the voltage detection circuit 930, if the output voltage Vout is less than the second threshold value −VH, the ratio control circuit 920 switches to the ratio generation circuit having a higher boost ratio according to the control signal Sctrl, such as switching to a ratio generation circuit 922_1 having a ratio of X-1.5. On the contrary, if the output voltage Vout is greater than the first threshold value −VL, the control circuit 620 switches to the ratio generation circuit having a lower boost ratio according to the control signal Sctrl, such as switching to a ratio generation circuit 922_2 having the ratio of X-2.5. The operation is similar to the charge pump module 600 disclosed in FIG. 7, it is omitted here.

Alternatively, the ratio control circuit may be implemented with four ratio generation circuits having different ratios X1.5, X2, X2.5 and X3, and the charge pump module may utilize the voltage detection circuit to detect the amount of voltage, so as to switch between the four ratios dynamically. Since, the voltage level of the output voltage reflects a size of the present load current, the ratio control circuit may dynamically auto adjust the ratio corresponding to different load currents, so as to achieve the purpose of power conservation.

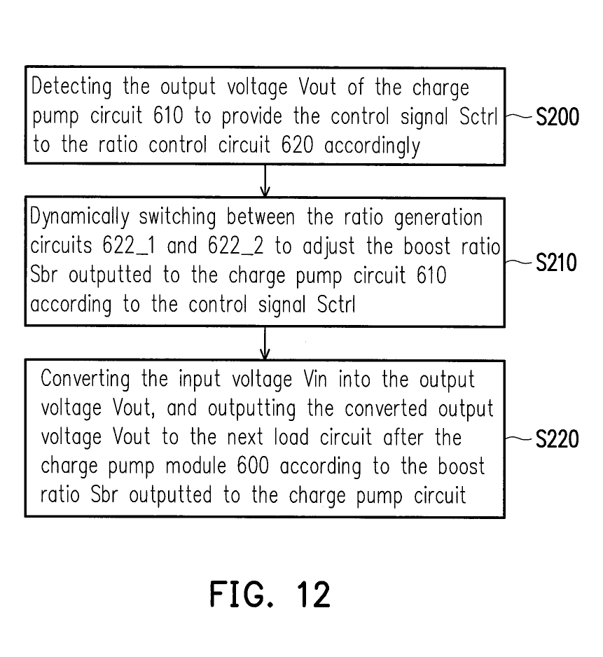

FIG. 12 is a flow chart illustrating a voltage generation method of a charge pump module according to yet another embodiment of the disclosure. With reference to FIGS. 7 and 12, the voltage generation method of the present embodiment is adapted to, for example, the output voltage Vout of the charge pump module 600 illustrated in FIG. 7, which includes the following steps. First of all, in step S200, the output voltage Vout of the charge pump circuit 610 is detected, so as to provide the control signal Sctrl to the ratio control circuit 620 accordingly. Next, in step S210, according to the control signal Sctrl, the ratio control circuit 610 dynamically switches between the ratio generation circuits 622_1 and 622_2 to adjust the boost ratio Sbr outputted to the charge pump circuit. Afterward, in step S220, according to the boost ratio Sbr outputted to the charge pump circuit, the input voltage Vin is converted to the output voltage Vout, and then outputted to the next load circuit (not shown) after the charge pump module 600.

Furthermore, the voltage generation method of the embodiment of the disclosure is sufficiently taught, suggested, and embodied in the embodiments illustrated in FIG. 7 thru FIG. 11, and therefore no further description is provided herein.

In summary, in the exemplary embodiments of the disclosure, the charge pump module switches between various boost ratios dynamically, so as to produce a ratio value equivalent to a ratio between the switched ratios. Furthermore, the charge pump module may also detect the voltage level of the output voltage to automatically adjust the ratio.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A charge pump module, comprising:
a ratio control circuit, providing a boost ratio according to a control signal, wherein the ratio control circuit comprises at least two ratio generation circuits having different boost ratios, and the ratio control circuit dynamically switches between the ratio generation circuits according to the control signal to adjust the provided boost ratio; and
a charge pump circuit, coupled to the ratio control circuit, receiving an input voltage, and converting the input voltage into an output voltage according to the boost ratio provided by the ratio control circuit.

2. The charge pump module according to claim 1, wherein the control signal comprises a first period and a second period, during the first period, the ratio control circuit switches to one of the ratio generation circuits according to the control signal, and during the second period, the ratio control circuit switches to another one of the ratio generation circuits according to the control signal.

3. The charge pump module according to claim 1, further comprising:
a voltage detection circuit, coupled to the charge pump circuit and the ratio control circuit, wherein the voltage detection circuit detects the output voltage, and accordingly provides the control signal to the ratio control circuit.

4. The charge pump module according to claim 3, wherein the control signal comprises a first period and a second period, the voltage detection voltage compares the output voltage with a first threshold value and a second threshold value to determine a duty cycle of the first period and the second period of the control signal.

5. The charge pump module according to claim 4, wherein the first threshold value is greater than the second threshold value, and according to a detection result of the voltage detection circuit, if the output voltage is less than the second threshold, the ratio control circuit switches to one of the ratio generation circuits having a higher boost ratio according to the control signal, and if the output voltage is greater than the first threshold, the ratio control circuit switches to one of the ratio generation circuits having a lower boost ratio according to the control signal.

6. The charge pump module according to claim 4, wherein the first threshold value and the second threshold value is determined according to a predetermined target value of the output voltage.

7. The charge pump module according to claim 1, wherein the ratio control circuit further comprises:
a ratio selection circuit, coupled to the ratio generation circuit, and dynamically switching to one of the ratio generation circuits according to the control signal.

8. The charge pump module according to claim 1, wherein the boost ratio of the ratio generation circuits are negative values, and the charge pump circuit provides the negative output voltage according to the negative boost ratio provided by the ratio control circuit.

9. The charge pump module according to claim 1, wherein the boost ratio of the ratio generation circuits are positive values, and the charge pump circuit provides the positive output voltage according to the positive boost ratio provided by the ratio control circuit.

10. The charge pump module according to claim 1, wherein the boost ratio provided by the ratio control circuit is between a maximum boost ratio and a minimum boost ratio of the switched ratio generation circuits.

11. A voltage generation method of a charge pump module, wherein the charge pump module comprises a ratio control circuit and a charge pump circuit, and the ratio control circuit comprises at least two ratio generation circuits having different boost ratios, wherein the voltage generation method comprises:
dynamically switching between the ratio generation circuits to adjust a boost ratio outputted to the charge pump circuit according to a control signal; and
converting an input voltage into an output voltage according to the boost ratio outputted to the charge pump circuit.

12. The voltage generation method according to claim 11, wherein the control signal comprises a first period and a second period, and the step of dynamically switching between the ratio generation circuits comprises:
during the first period, switching to one of the ratio generation circuits according to the control signal; and
during the second period, switching to another one of the ratio generation circuits according to the control signal.

13. The voltage generation method according to claim 11, further comprising:
detecting the output voltage to provide the control signal accordingly.

14. The voltage generation method according to claim 13, wherein the control signal comprises a first period and a second period, and the step of detecting the output voltage to provide the control signal accordingly comprises:
comparing the output voltage with a first threshold value and a second threshold value to determine a duty cycle of the first period and the second period of the control signal.

15. The voltage generation method according to claim 14, wherein the first threshold value is greater than the second threshold value, and the step of comparing the output voltage with the first threshold value and the second threshold value in the control signal comprises:
if the output voltage is less than the second threshold value, switching to one of the ratio generation circuits having a higher boost ratio according to the control signal; and
if the output voltage is greater than the first threshold value, switching to one of the ratio generation circuits having a lower boost ratio according to the control signal.

16. The voltage generation method according to claim 14, wherein the first threshold value and the second threshold value is determined according to a predetermined target value of the output voltage.

17. The voltage generation method according to claim 11, wherein the boost ratio of the ratio generation circuits are negative values, and in the step of converting the input voltage into the output voltage, the negative output voltage is provided according to the negative boost ratio outputted to the charge pump circuit.

18. The voltage generation method according to claim 11, wherein the boost ratio of the ratio generation circuits are positive values, and in the step of converting the input voltage into the output voltage, the positive output voltage is provided according to the positive boost ratio outputted to the charge pump circuit.

19. The voltage generation method according to claim 11, wherein the boost ratio outputted to the charge pump circuit is between a maximum boost ratio and a minimum boost ratio of the switching ratio generation circuits.
